(19) United States
(12) Patent Application Publication
(10) Pub. No.: US 2013/0248829 A1
(43) Pub. Date: Sep. 26, 2013

(54) SEMICONDUCTOR APPLICATION METHOD AND PRODUCT

(71) Applicant: Euan Smith, Cambridgeshire (GB)

(72) Inventor: Euan Smith, Cambridgeshire (GB)

(73) Assignee: Cambridge Display Technology Limited, Cambridgeshire (GB)

(21) Appl. No.: 13/803,810

(22) Filed: Mar. 14, 2013

(30) Foreign Application Priority Data
Mar. 23, 2012 (GB) GB1205139.7

(51) Int. Cl. H01L 51/00; H01L 27/32

(52) U.S. Cl. CPC H01L 51/0031; H01L 27/3244
USPC 257/40; 438/7

(57) ABSTRACT

A system and method for driving pixels of an OLED display using a backplane for an active matrix device comprising a substrate arranged to electrically connect to a plurality of semiconductor elements, a plurality of first semiconductor elements mounted on the substrate, each comprising one or more circuit elements configured to drive one or more active elements of the active matrix device, and a plurality of second semiconductor elements mounted on the substrate, each comprising one or more circuit elements configured to control one or more of the first semiconductor elements.

### FIELD OF THE INVENTION

This invention relates to active matrix OLED (Organic Light Emitting Diode) displays, in particular to a system and method for driving pixels of an OLED display.

### BACKGROUND

Recent years have seen very substantial growth in the market for displays as the quality of displays improves, their cost falls, and the range of applications for displays increases. This includes both large area displays such as for TVs or computer monitors and smaller displays for portable devices.

The most common classes of display presently on the market are liquid crystal displays and plasma displays although displays based on organic light-emitting diodes (OLEDs) are now increasingly attracting attention due to their many advantages including low power consumption, light weight, wide viewing angle, excellent contrast and potential for flexible displays.

The basic structure of an OLED is an organic light emissive layer, for instance a film of a poly (p-phenylenevinylene) (“PPV”) or polyfluorene, sandwiched between a cathode for injecting negative charge carriers (electrons) and an anode for injecting positive charge carriers (holes) into the organic layer. The electrons and holes combine in the organic layer generating photons. Suitable organic light emitting materials for use in the organic light-emitting layer include polymers, in particular conjugated polymers as disclosed in WO90/13148; the class of materials known as small molecule materials, such as (8-hydroxyquinoline) aluminum (“Alq3”) disclosed in U.S. Pat. No. 4,539,507, and dendrimers as disclosed in WO 99/21935. The light emitting layer may comprise a host material and one or more light-emitting fluorescent or phosphorescent dopants. In a practical device one of the electrodes is transparent, to allow the photons to escape the device.

A typical organic light-emissive device (“OLED”) is fabricated on a glass or plastic substrate coated with a transparent anode such as indium-tin-oxide (“ITO”). A layer of a thin film of at least one electroluminescent organic material is provided over the first electrode. Finally, a cathode is provided over the layer of electroluminescent organic material. The cathode is typically a metal or alloy and may comprise a single layer, such as aluminum, or a plurality of layers such as calcium and aluminum. Additional layers may be provided between the anode and cathode, in particular charge transporting and/or charge blocking layers.

The device may be pixellated with red, green and blue electroluminescent subpixels in order to provide a full color display.

Full color liquid crystal displays typically comprise a white-emitting backlight, and light emitted from the device is filtered through red, green and blue color filters after passing through the LC layer to provide the desired color image.

A full color display may be made in the same way by using a white or blue OLED in combination with color filters. Moreover, it has been demonstrated that use of color filters with OLEDs even when the pixels of the device already comprises red, green and blue subpixels can be beneficial. In particular, aligning red color filters with red electroluminescent subpixels and doing the same for green and blue subpixels and color filters can improve color purity of the display.

Downconversion, by means of color change media (CCMs) for absorption of emitted light and reemission at a desired longer wavelength or band of wavelengths, can be used as an alternative to, or in addition to, color filters.

One way of addressing displays such as LCDs and OLEDs is by use of an “active matrix” arrangement in which individual pixel elements of a display are activated by an associated thin-film transistor. The active matrix backplane for such displays can be made with amorphous silicon (a-Si) or low temperature polysilicon (LTPS). LTPS has high mobility but can be non-uniform and requires high processing temperature which limits the range of substrates that it can be used with. Amorphous silicon does not require such high processing temperature, however its mobility is relatively low, and can suffer from non-uniformities during use due to aging effects. Moreover, backplanes formed from either LTPS or a-Si both require processing steps such as photolithography, cleaning and annealing that can damage the underlying substrate. In the case of LTPS, in particular, a substrate that is resistant to these high-energy processes must be selected.

An alternative approach to patterning is disclosed in, for example, Rogers et al, Appl. Phys. Lett. 2004, 84(26), 5398-5400; Rogers et al Appl. Phys. Lett. 2006, 88, 213101- and Benkendorfer et al, Compound Semiconductor, June 2007, in which silicon on an insulator is patterned using conventional methods such as photolithography into a plurality of semiconductor elements (hereinafter referred to as “chiplets”) which are then transferred to a device substrate. The transfer printing process takes place by bringing the plurality of chiplets into contact with an elastomeric stamp which has surface chemical functionality that causes the chiplets to bind to the stamp, and then transferring the chiplets to the device substrate. In this way, chiplets carrying micro- and nano-scale structures such as display driving circuitry can be transferred with good registration onto an end substrate which does not have to tolerate the demanding processes involved in silicon patterning.

### SUMMARY OF THE INVENTION

In a first aspect, the invention provides a backplane for an active matrix device comprising:

a substrate arranged to electrically connect to a plurality of semiconductor elements:

a plurality of first semiconductor elements mounted on the substrate, each first semiconductor element comprising one or more circuit elements configured to drive one or more active elements of the active matrix device; and

a plurality of second semiconductor elements mounted on the substrate, each second semiconductor element comprising one or more circuit elements configured to control one or more of the first semiconductor elements.

Preferably said one or more circuit elements of each of the first semiconductor elements is configured to drive one or more active elements of the active matrix device with an analogue drive signal; and

said one or more circuit elements of each of the second semiconductor elements is configured to control one or more of the first semiconductor elements with a digital control signal.

Preferably at least some of the second semiconductor elements comprise further circuit elements in addition to the one or more circuit elements configured to control the first semiconductor elements.

Preferably the analogue drive signals have a higher power than the digital control signals.

Preferably the analogue drive signals have a higher current than the digital control signals.

Preferably the circuit elements of the second semiconductor elements have a higher component density than the circuit elements of the first semiconductor elements.

Preferably the second semiconductor elements have a higher component density than the first semiconductor elements.

Preferably each of the first semiconductor elements is individually addressable.

Preferably the backplane is for an active matrix light-emitting device.

Preferably the backplane is for an active matrix OLED.

Preferably the backplane is for an active matrix sensor device.

Preferably the backplane is for a photovoltaic device.

In a second aspect, the invention provides a method applying semiconductor elements to a substrate comprising the steps of:

defining a primary element position on a substrate for application of a semiconductor element of a first type;

defining a secondary element position on the substrate for applying a semiconductor element of the first type;

defining a further element position on the substrate for applying a semiconductor element of a second type;

attempting to apply a semiconductor element of the first type onto the substrate in the primary position;

checking whether or not the application of the semiconductor element of the first type in the primary position has been successful; and

if said checking indicates that the application of the semiconductor element of the first type in the primary position has not been successful, attempting to apply a semiconductor element of the first type onto the substrate at the secondary position; and

applying a semiconductor element of a second type in the further position;

wherein the further element position is electrically connected to the primary element position and the secondary element position, and functionality of electrical connections from the primary element position to other parts of the substrate are duplicated at the secondary element position; and

the semiconductor element of the second type comprises one or more circuit elements arranged to determine whether a semiconductor element of the first type is present at the primary element position or the secondary element position, and to provide control signals to the semiconductor element of the first type.

Preferably said attempting to apply a semiconductor element of the first type to the substrate at the first and/or secondary position comprises attempting to print the semiconductor element of the first type, preferably attempting to transfer print the semiconductor element.

Preferably said defining a primary element position comprises defining a plurality of primary element positions for attempted application of a corresponding plurality of semiconductor elements;

said defining a secondary element position comprises defining a plurality of secondary element positions each corresponding to a respective primary element positions;

said defining a further element position comprises defining a plurality of further element positions;

said attempting to apply comprises checking whether or not the application of a semiconductor element of the first type in each primary position has been successful; and

if said checking indicates that the application of the semiconductor element of the first type in a primary position has not been successful, attempting to apply a semiconductor element of the first type onto the substrate at the respective corresponding secondary position.

Preferably said checking comprises visually checking whether a semiconductor element of the first type is present at the, or each, primary position.

Preferably said checking comprises visually checking whether any semiconductor element of the first type present at the, or each, primary position is correctly aligned.

Preferably said checking comprises electrically checking the function of the semiconductor element of the first type intended to be present at the, or each, primary position.

Preferably the checking is carried out automatically.

Preferably at least some of the semiconductor elements of the second type comprise further circuit elements in addition to the one or more circuit elements configured to provide control signals to the semiconductor element of the first type.

Preferably each semiconductor element of the first type comprises one or more circuit elements configured to provide drive signals to one or more active elements of an active matrix device.

Preferably the drive signals are analogue signals and control signals are digital signals.

Preferably the analogue drive signals have a higher power than the digital control signals.

Preferably the analogue drive signals have a higher current than the digital control signals.

Preferably the circuit elements of the semiconductor element of the second type has a higher component density than the circuit elements of the semiconductor element of the second type.

Preferably the semiconductor element of the second type has a higher component density than the semiconductor element of the first type.

Preferably each semiconductor element of the second type is individually addressable.

Preferably the one or more circuit elements of the semiconductor element of the first type are drive circuit elements for addressing one or more pixels or subpixels of an active matrix light-emitting device.

Preferably the active matrix light-emitting device is an active matrix OLED.

### BRIEF DESCRIPTION OF THE DRAWINGS

For a better understanding of the invention and as to how the same may be carried into effect, reference will now be made, by way of example only, to the accompanying drawings, in which:

FIG. 1 illustrates a chiplet of a backplane;

FIG. 2 illustrates a backplane;

FIG. 3 illustrates a backplane according to a first embodiment of the invention;

FIG. 4 illustrates a backplane according to a second embodiment of the invention; and

FIG. 5 illustrates an OLED device incorporating an embodiment of the invention.

### DETAILED DESCRIPTION OF THE INVENTION

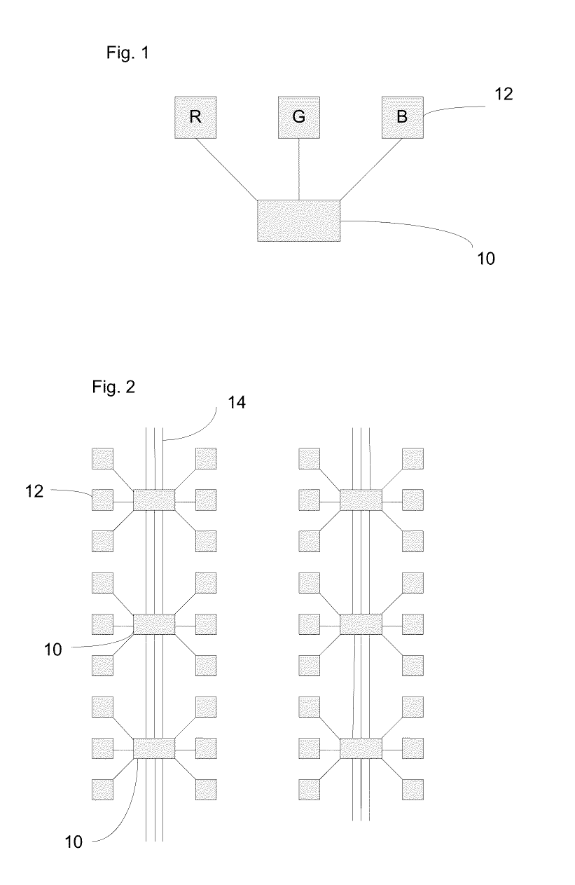

FIG. 1 illustrates a chiplet 10 of a backplane that drives a pixel comprising a red, green and blue subpixel 12. It will be appreciated that each chiplet may drive a larger or smaller number of subpixels; that each chiplet may drive a plurality of pixels; that the pixels or subpixels driven by a given chiplet may have the same or different colors; and that a pixel driven by a given chiplet may comprise subpixels other than red, green and blue subpixels.

A plurality of chiplets 10 of the backplane are provided to drive an array of pixels making up an OLED display. The chiplets 10 are provided with power and control data along data and power drive lines so that the chiplets 10 can drive the pixels to operate the OLED display.

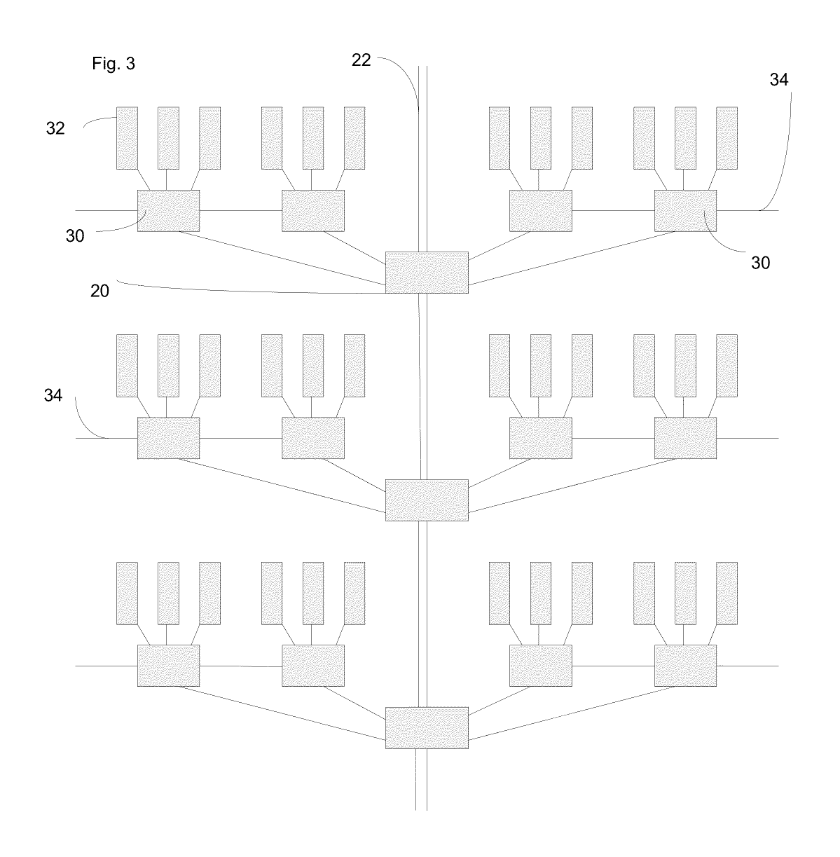

FIG. 2 illustrates a possible backplane arrangement where groups of chiplets 10 are arranged in columns along each of a plurality of drive lines 14. In this example each chiplet 10 drives two pixels comprising red, green and blue subpixels 12 using power and control data supplied along a respective drive line 14. Each drive line 14 comprises a plurality of individual data drive lines and power drive lines to provide the necessary drive power and data.

The chiplets 10 in the above example process received digital control data signals and control the supply of power to the associated subpixels based upon the results of this processing. These power supplies to the subpixels are analogue signals and in practice these power supplies will generally require much higher currents than the digital control data signals.

Accordingly, the chiplets 10 are hybrid devices which handle both relatively low current digital control signals and relatively high current analogue power signals. It has been realised that this hybrid nature of the chiplets 10 can result in problems in the design and manufacture of the chiplets 10. These problems can arise because of the different requirements of the digital and analogue parts of the chiplets 10, and particularly the different values of the electrical currents of the signals the digital and analogue parts of the chiplets 10 are required to carry. In general, in order to support the higher analogue drive currents, the components of the parts of the chiplets 10 handling the analogue power signals are larger in area than the components of the parts of the chiplets 10 handling the digital control signals.

In practice all of the components on each chiplet 10 are formed from a semiconductor material by a single common semiconductor fabrication process. In semiconductor manufacture it is generally desirable to match the fabrication process to the required dimensions of the components which are to be formed. Different fabrication processes generally have a minimum component dimension which they can reliably define. This is usually expressed as the minimum length of a linear feature which can be formed by the process, but it will be understood that this corresponds to other minimum dimensions such as widths and areas. Fabrication processes which are able to form components having smaller minimum dimensions are commonly described as higher density processes, while fabrication processes which are only able to form components having larger minimum dimensions are commonly described as lower density processes.

It has been realized that if the fabrication process used to form the chiplets 10 is a lower density process matched to the dimensions required by the high current analogue power signal components of the chiplets 10, the minimum dimensions of the digital control signal components is unnecessarily large, limiting the component density at which the digital signal components can be formed. If the fabrication process is used to form the chiplets 10 is instead a higher density process matched to the dimensions required by the low current digital power signal components of the chiplets 10, the high density fabrication process can also form the dimensions of the analogue power signal components with the desired dimensions. However, this approach of forming the relatively large area analogue power components using a high density fabrication process may be undesirably costly because, in general, higher density fabrication processes are more costly to carry out.

FIG. 3 illustrates an embodiment of the present invention in which a plurality of chiplets are formed on a backplane of an OLED display. The backplane is provided with a plurality of each of two different types of chiplets, control chiplets 20 and power chiplets 30.

In this embodiment each control chiplet 20 of the backplane controls four power chiplets 30. The control chiplets 20 are located in a plurality of groups, with the control chiplets 30 of each group arranged in a column along a data bus 22. Each control chiplet 20 processes data signals received from the data bus 22 to generate control signals for each of the power chiplets 30 controlled by the control chiplet 20.

Each power chiplet 30 drives a pixel comprising a red, green and blue subpixel 32. Each power chiplet 30 is connected to power supply lines 34, and provides electrical power from the power supply lines 34 to the subpixels 32 to drive the subpixels 32 as instructed by the control signals received by the power chiplet 30 from the associated control chiplet 20.

A plurality of data busses will be arranged in parallel across the substrate to control pixels distributed across the OLED display.

It will be appreciated that each control chiplet may control a larger or smaller number of power chiplets. It will be appreciated that each power chiplet may drive a larger or smaller number of subpixels; that each power chiplet may drive a plurality of pixels; that the pixels or subpixels driven by a given power chiplet may have the same or different colours; and that a pixel driven by a given power chiplet may comprise subpixels other than red, green and blue subpixels.

In the embodiment illustrated in FIG. 3 each power chiplet drives a single pixel. As discussed above, in alternative embodiments each power chiplet may drive a plurality of pixels. However, in practice it may be difficult to route the conductors carrying the power signals from a power chiplet to the sub-pixels over long distances, so it may be preferred to arrange each power chiplet to drive only a small number of pixels so that the power chiplet can be located relatively close to all of the associated sub-pixels and the conductors carrying the power signals kept short.

Accordingly, in the present invention the digital processing functions are carried out by the control chiplets 20 on digital control data signals while the power supply functions are carried out by the power chiplets 30 on analogue power signals. This separation of the relatively low power digital functions and relatively high power analogue functions onto separate chiplets allows each type of chiplet to be separately fabricated using a fabrication technique selected to be appropriate for the desired dimensions of the components on the chiplet. This allows the components on the control chiplets 20 to be fabricated with a high component density without the overall cost of the chiplets becoming excessive.

As shown in FIG. 3, separating the relatively low power digital functions and relatively high power analogue functions onto separate chiplets allows the digital processing functionality for a group of pixels and their associated power chiplets to be centralized on a single control chiplet. This may provide the advantage of allowing additional processing functionality to be added to the digital control chip at a lower cost than would be the case if hybrid chiplets were used, where the additional processing functionality would have to be added to each of the hybrid chiplets.

Forming the components on the control chiplets with a high component density in this way may also allow the power consumption of the OLED display to be reduced. Digital components fabricated with appropriate component dimensions by a high density fabrication technique will generally consume less power than digital components fabricated with needless large dimensions, as may be the case when a single hybrrd chiplet is used.

The control chiplets may be formed by a high density semiconductor fabrication process. In some examples the control chiplets may be formed using a 65 nm semiconductor fabrication process or a 45 nm semiconductor fabrication process.

The power chiplets may be formed by a high density semiconductor fabrication process. In some examples the power chiplets may be formed using a 0.6 μm semiconductor fabrication process, or a 0.35 μm semiconductor fabrication process, or a 0.25 μm semiconductor fabrication process.

The use of separate power and control chiplets according to the present invention can be combined with a manufacturing process using alternative landing areas for chiplets.

Manufacturing processes of this type are described, for example in our co-pending applications nos. GB1111740.5 and GB1111741.3.

In an alternate landing area manufacturing process, in addition to defining a desired location on the substrate where it is intended to print a chiplet, the primary chiplet landing area, an alternative backup location on the substrate where a replacement chiplet can also be printed, the secondary chiplet landing area, is also defined. The primary chiplet landing area on the substrate defines conductive elements for electrical connection to a chiplet, as is conventional. At the secondary chiplet landing area, in addition to leaving the necessary physical area clear to allow a chiplet to be located on the substrate, the substrate defines conductive elements for electrical connection to a chiplet duplicating those provided at the primary chiplet landing area.

In practice, the process of printing of a plurality of chiplets to desired positions on a substrate, for example to provide a backplane for an active matrix light-emitting device such as an OLED, may be imperfect. In particular one or more chiplets that are intended to be printed onto a substrate may in fact fail to print correctly. The failure of a chiplet to print correctly may result in a chiplet being entirely absent from the desired position on the substrate. This may be due to factors such as particulates on the substrate surface preventing transfer of one or more chiplets from the stamp to the substrate or failure of chiplets to bind to the stamp before transfer to the substrate.

The failure of a chiplet to print correctly may alternatively result in a chiplet being present but not precisely at the desired position, that is, the chiplet may be present but misaligned from the desired position. For example, the chiplet may be linearly offset from the desired position and/or rotationally offset from the desired orientation. This may be due to factors such as misalignment of the stamp to the substrate or misalignment of chiplets on the stamp before transfer to the substrate.

Clearly, if a chiplet is not present at a desired position this will prevent correct operation of the backplane because required circuit elements will not be present. Similarly, if a chiplet is present at a desired position but misaligned this will also prevent correct operation of the backplane if the misalignment causes any of the intended connections between the chiplet and conductors on the substrate to not be made or to be incorrectly made.

Further, in practice, both the chiplets themselves and the processes used to form electrical connections between the chiplets and conductors on the substrate are imperfect, so that one or more chiplets that are correctly printed onto the substrate may not function due to an absent connection between the chiplet and the substrate or a fault in the chiplet, and so prevent correct operation of the backplane.

The substrate can be checked after printing in order to identify any desired positions where chiplets have failed to print correctly. This checking could for example be carried out by an automated visual checking system using a camera to check whether a chiplet is present at each of the desired positions.

In addition to detecting whether a chiplet is present at each of the desired positions, the checking after printing in order to identify any desired positions where chiplets have failed to print correctly may also detect misaligned chiplets. When this checking is for example carried out by an automated visual checking system using a camera to check whether a chiplet is present at each of the desired positions, the automated visual checking system may also be able to detect when a chiplet is misaligned.

After the printing a further operation may be carried out to form electrical and physical connections between the chiplets and the substrate. In particular, this further operation could be comprise forming a planarization layer over the chiplets, followed by the deposition and photolithographic processing of a metal layer over the planarization layer, for example. The substrate can be checked after this further operation in order to identify any chiplets which fail to function correctly. This checking could for example be carried out by an automated electrical checking system using contact probes to apply test voltages and currents to check whether each chiplet is functioning correctly. Such a test of correct chiplet function will identify any desired chiplets which are not functioning correctly for any reason, for example, due to the chiplet not being present, the chiplet being misaligned, a connection between the chiplet and the substrate not being made, or a fault on the chiplet.

When an alternate landing area manufacturing process is used, if a chiplet which should have been printed at a primary chiplet landing area is found to be non-functional, a replacement pixel can be printed at the corresponding secondary chiplet landing area. The chiplet at the secondary chiplet landing area can then be used in place of the non-functional chiplet which should have been printed at the primary chiplet landing area.

In practice, it may not be necessary to distinguish between chiplets that are present but misaligned, chiplets that are present but not properly electrically connected and chiplets which are present but faulty, since all three cases can be regarded as non-functional and in all three cases the same remedial action is taken of replacing the non-functional chiplet with a chiplet at the secondary chiplet landing area.

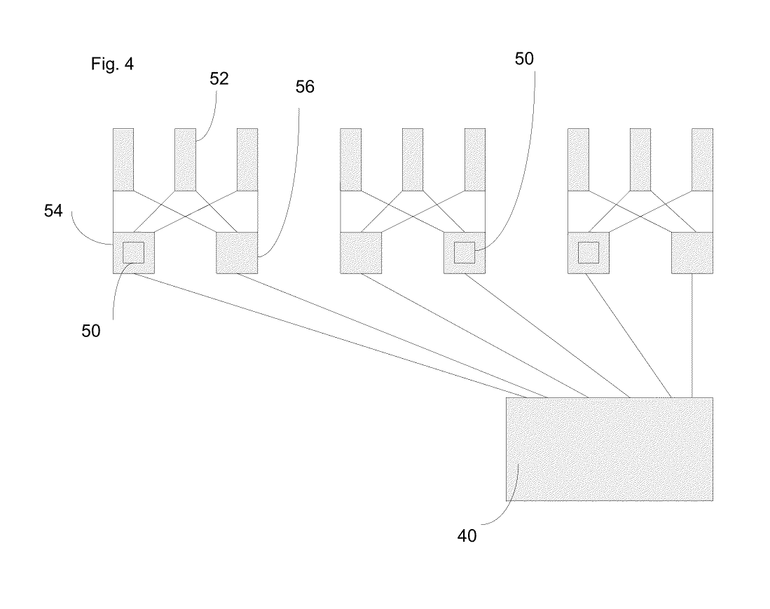

FIG. 4 illustrates an embodiment of the present invention in which a plurality of chiplets are formed on a backplane of an OLED display. The backplane is provided with a plurality of each of two different types of chiplets, control chiplets 40 and power chiplets 50.

In this embodiment each control chiplet 40 of the backplane controls three power chiplets 50. The control chiplet 40 processes data signals to generate control signals for each of the power chiplets 50 controlled by the control chiplet 40.

Each power chiplet 50 drives a pixel comprising a red, green and blue subpixel 52. Each power chiplet 50 provides electrical power to the subpixels 52 to drive the subpixels 52 as instructed by the control signals received by the power chiplet 50 from the associated control chiplet 40.

In FIG. 4 only a single control chiplet 40 and the associated power chiplets 590 are shown. It will be understood that a plurality of chiplets 40 and 50 of the backplane are provided to drive an array of pixels making up an OLED display. The chiplets are provided with power and control data along data and power drive lines so that the chiplets can drive the pixels to operate the OLED display.

It will be appreciated that each control chiplet may control a larger or smaller number of power chiplets. It will be appreciated that each power chiplet may drive a larger or smaller number of subpixels; that each power chiplet may drive a plurality of pixels; that the pixels or subpixels driven by a given power chiplet may have the same or different colors; and that a pixel driven by a given power chiplet may comprise subpixels other than red, green and blue subpixels.

In this embodiment each power chiplet location has a defined primary landing area 54 and a defined secondary landing area 56.

During manufacture it is first attempted to print a power chiplet 50 at each power chiplet location primary landing area 54. The backplane is then examined as discussed above, and if any of the power chiplet locations are determined to be non-functional it is attempted to print a power chiplet 50 at the corresponding power chiplet location secondary landing area 56.

Conductive connections are provided between both of the power chiplet location primary landing area 54 and the power chiplet location secondary landing area 56 at each power chiplet location and the sub-pixels 52 and control chiplet 40 associated with that power chiplet location.

The control chiplet 40 is provided with processing functionality enabling the control chiplet 40 to determine which conductive connections are linked to a functional power chiplet 50 so that the control chiplet 50 can determine whether the power chiplet 40 is located at the primary landing area 54 or the secondary landing area 56 at each of the associated power chiplet locations. The control chiplet 40 can then send control signals to the landing area where each of the associated power chiplets 50 is actually located.

In one embodiment the conductive connections to the power chiplet location primary landing area 54 and the power chiplet location secondary landing area 56 of each power chiplet location may be connected to separate pins or connectors of the associated control chiplet 40. When the backplane is activated the control chiplet 40 can generate test signals to determine which pins or connectors are linked to a functional power chiplet 50.

In alternative embodiments the backplane may be inspected to determine whether a functional power chiplet is located at the primary landing area or the secondary landing area at each power chiplet location, and each control chiplet provided with data identifying the locations of the associated functional power chiplets.

### Chiplet Material

The chiplets may be formed from semiconductor wafer sources, including bulk semiconductor wafers such as single crystalline silicon wafers, polycrystalline silicon wafers, germanium wafers; ultra thin semiconductor wafers such as ultra thin silicon wafers; doped semiconductor wafers such as p-type or n-type doped wafers and wafers with selected spatial distributions of dopants; semiconductor on insulator wafers such as silicon on insulator (e.g. Si-SiO2, SiGe); and semiconductor on substrate wafers such as silicon on substrate wafers. In addition, printable semiconductor elements of the present invention may be fabricated from a variety of nonwafer sources, such as a thin films of amorphous, polycrystalline and single crystal semiconductor materials (e.g. polycrystalline silicon, amorphous silicon, polycrystalline GaAs and amorphous GaAs) that is deposited on a sacrificial layer or substrate (e.g. SiN or SiO2) and subsequently annealed, and other bulk crystals, including, but not limited to, graphite, MoSe2 and other transition metal chalcogenides, and yttrium barium copper oxide.

The chiplets may be formed by conventional processing means known to the skilled person. One or more circuit elements may be provided on the chiplet depending on the required functionality of the chiplet.

Preferably, each chiplet is up to 500 microns in length, preferably between about 15-250 microns, and preferably about 5-50 microns in width, more preferably 5-10 microns.

### Chiplet Application Process

The stamp used in transfer printing of chiplets is preferably a PDMS stamp.

The surface of the stamp may have a chemical functionality that causes the chiplets to reversibly bind to the stamp and lift off the donor substrate, or may bind by virtue of, for example, van der Waals force. Likewise upon transfer to the end substrate, the chiplets adhere to the end substrate by van der Waals force and/or by an interaction with a chemical functionality on the surface of the end substrate, and as a result the stamp may be delaminated from the chiplets.

### Chiplet and Display Integration

To ensure accurate transfer onto a prepared end substrate, the stamp and end substrate may be registered by means known to the skilled person, for example by providing alignment marks on the substrate.

In the case where the chiplets drive a display such as an LCD or OLED display, electrodes of the display device are connected to the output of the chiplets by means of conducting through-vias formed in the planarisation layer.

### Organic LED

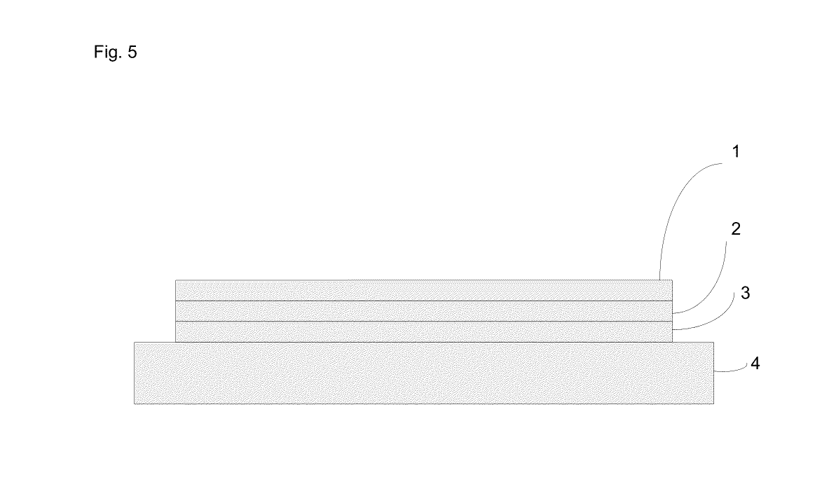

A suitable OLED construction is illustrated in FIG. 5 for the case where the light-emitting device is an OLED. The backplane (not shown) is formed on a glass or plastic substrate 1 and connected to an anode 2 of the OLED. The OLED further comprises a cathode 4 and an organic light-emitting layer 3 between anode 2 and cathode 4.

In a practical device, at least one of the electrodes is semi-transparent in order that light may be emitted. Where the anode is transparent, it typically comprises indium tin oxide. In one arrangement, the cathode is transparent in order to avoid the problem of light emitted from organic light-emitting layer 3 being absorbed by the chiplets and other associated drive circuitry in the case where light is emitted through the anode. A transparent cathode typically comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminum. Examples of transparent cathode devices are disclosed in, for example, GB 2348316.

Suitable materials for use in organic light-emitting layer 3 include small molecule, polymeric and dendrimeric materials, and compositions thereof. Suitable electroluminescent polymers for use in layer 3 include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein. Suitable electroluminescent dendrimers for use in layer 3 include electroluminescent metal complexes bearing dendrimeric groups as disclosed in, for example, WO 02/066552.

Further layers may be located between anode 2 and cathode 3, such as charge transporting, charge injecting or charge blocking layers.

The device is preferably encapsulated with an encapsulant (not shown) to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

FIG. 5 illustrates a device wherein the device is formed by firstly forming an anode on a substrate followed by deposition of an organic light-emitting layer and a cathode, however it will be appreciated that the device of the invention could also be formed by firstly forming a cathode on a substrate followed by deposition of an electroluminescent layer and an anode. The method described herein may be applied in manufacture of devices and components other than display backplanes. For example, the method may be used to form sensors wherein each chiplet is sensitive to the parameter being measured (e.g. temperature, x-rays) or photovoltaic devices in which each chiplet on the substrate functions as an individual micro-scale photovoltaic element. It will be understood that this may require the chiplets to have different functionality than in an OLED.

It will be understood that the numbers and geometry of the conductive lines and pads and the identified functions of the conductive lines in the illustrated embodiments are explanatory examples only and that the invention is not limited to the specific arrangements disclosed.

Those skilled in the art will appreciate that while this disclosure has described what is considered to be the best mode and, where appropriate, other modes of performing the invention, the invention should not be limited to the specific configurations and methods disclosed in this description of the preferred embodiment.

1. A backplane for an active matrix device comprising:
a substrate arranged to electrically connect to a plurality of semiconductor elements:
a plurality of first semiconductor elements mounted on the substrate, each first semiconductor element comprising one or more circuit elements configured to drive one or more active elements of the active matrix device; and
a plurality of second semiconductor elements mounted on the substrate, each second semiconductor element comprising one or more circuit elements configured to control one or more of the first semiconductor elements.

2. The backplane according to claim 1 wherein said one or more circuit elements of each of the first semiconductor elements is configured to drive one or more active elements of the active matrix device with an analog drive signal; and
said one or more circuit elements of each of the second semiconductor elements is configured to control one or more of the first semiconductor elements with a digital control signal.

3. The backplane according to claim 2 wherein at least some of the second semiconductor elements comprise further circuit elements in addition to the one or more circuit elements configured to control the first semiconductor elements.

4. The backplane according to claim 1 wherein the analog drive signals have a higher power than the digital control signals.

5. The backplane according to claim 1 wherein the analog drive signals have a higher current than the digital control signals.

6. The backplane according to claim 1 wherein the circuit elements of the second semiconductor elements have a higher component density than the circuit elements of the first semiconductor elements.

7. The backplane according to claim 6 wherein the second semiconductor elements have a higher component density than the first semiconductor elements.

8. The backplane according to claim 1 wherein each of the first semiconductor elements is individually addressable.

9. The backplane according to claim 1 wherein the backplane is for an active matrix light-emitting device.

10. The backplane according to claim 9 wherein the backplane is for an active matrix OLED.

11. The backplane according to claim 1 wherein the backplane is for an active matrix sensor device.

12. The backplane according to claim 1 wherein the backplane is for a photovoltaic device.

13. A method applying semiconductor elements to a substrate comprising the steps of:
defining a primary element position on a substrate for application of a semiconductor element of a first type;
defining a secondary element position on the substrate for applying a semiconductor element of the first type;
defining a further element position on the substrate for applying a semiconductor element of a second type;
attempting to apply a semiconductor element of the first type onto the substrate in the primary position;
checking whether or not the application of the semiconductor element of the first type in the primary position has been successful; and
if said checking indicates that the application of the semiconductor element of the first type in the primary position has not been successful, attempting to apply a semiconductor element of the first type onto the substrate at the secondary position; and
applying a semiconductor element of a second type in the further position;
wherein the further element position is electrically connected to the primary element position and the secondary element position, and functionality of electrical connections from the primary element position to other parts of the substrate are duplicated at the secondary element position; and
the semiconductor element of the second type comprises one or more circuit elements arranged to determine whether a semiconductor element of the first type is present at the primary element position or the secondary element position, and to provide control signals to the semiconductor element of the first type.

14. The method according to claim 13 wherein said attempting to apply a semiconductor element of the first type to the substrate at the first and/or secondary position comprises attempting to print the semiconductor element of the first type, preferably attempting to transfer print the semiconductor element.

15. The method according to claim 13 wherein:
said defining a primary element position comprises defining a plurality of primary element positions for attempted application of a corresponding plurality of semiconductor elements;
said defining a secondary element position comprises defining a plurality of secondary element positions each corresponding to a respective primary element positions;
said defining a further element position comprises defining a plurality of further element positions;
said attempting to apply comprises checking whether or not the application of a semiconductor element of the first type in each primary position has been successful; and
if said checking indicates that the application of the semiconductor element of the first type in a primary position has not been successful, attempting to apply a semiconductor element of the first type onto the substrate at the respective corresponding secondary position.

16. The method according to any claim 13 wherein said checking comprises visually checking whether a semiconductor element of the first type is present at the, or each, primary position.

17. The method according to claim 13 wherein said checking comprises visually checking whether any semiconductor element of the first type present at the, or each, primary position is correctly aligned.

18. The method according to any one of claim 13 wherein said checking comprises electrically checking the function of the semiconductor element of the first type intended to be present at the, or each, primary position.

19. The method according to claim 13 wherein the checking is carried out automatically.

20. The backplane according to claim 13 wherein at least some of the semiconductor elements of the second type comprise further circuit elements in addition to the one or more circuit elements configured to provide control signals to the semiconductor element of the first type.

21. The method according to claim 13 wherein each semiconductor element of the first type comprises one or more circuit elements configured to provide drive signals to one or more active elements of an active matrix device.

22. The method according to claim 21 wherein the drive signals are analog signals and control signals are digital signals.

23. The method according to claim 22 wherein the analog drive signals have a higher power than the digital control signals.

23. The method according to claim 22 wherein the analog drive signals have a higher current than the digital control signals.

24. The method according to claim 13 wherein the circuit elements of the semiconductor element of the second type have a higher component density than the circuit elements of the semiconductor element of the second type.

25. The method according to claim 24 wherein the semiconductor element of the second type has a higher component density than the semiconductor element of the first type.

26. The method according to claim 13 wherein each semiconductor element of the second type is individually addressable.

27. The method according to claim 20 wherein the one or more circuit elements of the semiconductor element of the first type are drive circuit elements for addressing one or more pixels or subpixels of an active matrix light-emitting device.

28. The method according to claim 27 wherein the active matrix light-emitting device is an active matrix OLED.
